(19) United States
(12) Patent Application Publication
(10) Pub. No.: US 2021/0226067 A1
(43) Pub. Date: Jul. 22, 2021

(54) THIN FILM TRANSISTOR AND METHOD FOR FABRICATING THE SAME, ARRAY SUBSTRATE AND DISPLAY PANEL

(71) Applicant: BOE TECHNOLOGY GROUP CO., LTD., Beijing (CN)

(72) Inventors: Guoying WANG, Beijing (CN); Zhen SONG, Beijing (CN)

(21) Appl. No.: 16/097,486

(22) PCT Filed: Mar. 2, 2018
(86) PCT No.: PCT/CN2018/077928

§ 371 Date: Oct. 29, 2018

(30) Foreign Application Priority Data
May 4, 2017 (CN) 201710307274.9

(51) Int. Cl. H01L 29/786; H01L 29/417; H01L 29/66

(52) U.S. Cl. CPC H01L 29/78633; H01L 29/41733; H01L 29/7869; H01L 29/66969; H01L 29/78603

(57) ABSTRACT

The present disclosure provides a thin film transistor and a method for fabricating the same, an array substrate, and a display panel for enhancing the light shielding effect on a channel region of a thin film transistor, improving the light stability of the thin film transistor and improving the operational stability of the thin film transistor. The thin film transistor according to embodiments of the disclosure includes a light shielding layer and a buffer layer on the light shielding layer, an active layer on the buffer layer, and the active layer includes a channel region, a source region, and a drain region located on two sides of the channel region, the buffer layer being disposed such that light cannot be incident to the channel region via the buffer layer.

### CROSS REFERENCE TO RELATED APPLICATIONS

This patent application is a National Stage Entry of PCT/CN2018/077928 filed on Mar. 2, 2018, which claims the benefit and priority of Chinese Patent Application No. 201710307274.9 filed on May 4, 2017, the disclosures of which are incorporated herein by reference in their entirety as part of the present application.

### BACKGROUND

The present disclosure relates to a field of display technologies, and in particular, to a thin film transistor, a method for fabricating the same, an array substrate, and a display panel.

In an oxide thin film transistor (TFT) with a top gate structure, the gate region does not overlap with the source region or the drain region. Thus, the parasitic capacitance (Cgs) is small. Therefore, the TFT can be applied to organic light-emitting diode (OLED) display products with high resolution, high refresh rate, large-size, narrow bezel, and low power consumption. However, since the oxide in the oxide TFT is sensitive to light, the electrical properties of the oxide in the channel region of the TFT change with illumination. For the oxide TFT with the top gate structure, compared with TFT of the bottom gate structure, there is no shielding of the bottom gate to the channel. The TFT is prone to a large threshold voltage (VTH) drift, which exceeds the compensation range of the compensation circuit, causing problems such as residual images on the display screen.

### BRIEF DESCRIPTION

Embodiments of the present disclosure provide a thin film transistor. The thin film transistor includes a light shielding layer, a buffer layer on the light shielding layer, and an active layer on the buffer layer. The active layer includes a channel region and a source region and a drain region respectively on two sides of the channel region. A thickness of the buffer layer is set such that light cannot be incident to the channel region via the buffer layer.

The thin film transistor provided by the embodiments of the present disclosure can prevent light from entering the channel region through the buffer layer due to the thickness of the buffer layer. Thereby the light shielding effect on the channel region of the thin film transistor may be enhanced and the light stability of the thin film transistor may be improved. Therefore, the operational stability of the thin film transistor can be improved.

In an embodiment, the light shielding layer includes a metal and the buffer layer includes a metal oxide. In an embodiment, the material of the light shielding layer includes a molybdenum-niobium alloy, and the material of the buffer layer includes aluminum oxide.

In an embodiment, the aluminum oxide is formed by anodizing an aluminum-neodymium alloy.

In an embodiment, the buffer layer has a thickness in the range of about 100 nm to about 200 nm.

In an embodiment, a projection of the buffer layer on the light shielding layer falls within the light shielding layer.

In an embodiment, the thin film transistor further includes a gate insulating layer on the channel region, a gate electrode on the gate insulating layer, an insulating layer on the gate electrode, the source region, the drain region, the buffer layer, and the light shielding layer, and a source electrode and a drain electrode on the insulating layer. The insulating layer includes a first via, a second via, and a third via. The source electrode and the drain electrode are connected to the source region and the drain region through the first via and the second via respectively. One of the drain electrode and the drain is connected to the light shielding layer through the third via.

In an embodiment, a thickness of the buffer layer is further set such that light cannot be incident to the source region or the drain region via the buffer layer.

An array substrate provided by the embodiment of the present disclosure includes the thin film transistor provided by the embodiment of the present disclosure.

A display panel provided by the embodiment of the present disclosure includes the array substrate provided by the embodiment of the present disclosure.

Embodiments of the present disclosure provide a method for fabricating a thin film transistor. The method includes forming a light shielding layer on the base substrate, forming a buffer layer on the light shielding layer, and forming an active layer on the buffer layer. The active layer includes a channel region and source and drain regions respectively on two sides of the channel region. The thickness of the buffer layer is set such that light cannot be incident to the channel region via the buffer layer.

In an embodiment, the light shielding layer includes a metal and the buffer layer includes a metal oxide.

In an embodiment, forming the light shielding layer and forming the buffer layer includes forming a first metal layer as the light shielding layer on the substrate, forming a second metal layer on the first metal layer, and performing an oxidation treatment on the second metal layer to form the buffer layer.

In an embodiment, the first metal includes a molybdenum-niobium alloy and the second metal layer includes an aluminum-neodymium alloy. The oxidation treatment includes anodizing the aluminum-neodymium alloy to obtain aluminum oxide.

In an embodiment, the thin film transistor fabrication method further includes forming a gate insulating layer on the channel region, forming a gate electrode on the gate insulating layer, forming an insulating layer on the gate electrode, the source region, the drain region, the buffer layer, and the light shielding layer, forming a first via, a second via, and a third via on the insulating layer, and forming a source electrode and a drain electrode on the interlayer insulating layer. The first via reaches an upper surface of the source region, the second via reaches an upper surface of the drain region, and the third via reaches an upper surface of the light shielding layer not covered by the buffer layer. The source electrode and the drain electrode are connected to the source region and the drain region through the first via and the second via respectively. One of the source electrode and the drain electrode is connected to the light shielding layer through the third via.

In an embodiment, forming the first via, the second via, and the third via are formed in the same etching process.

In an embodiment, a thickness of the buffer layer is further set such that light cannot be incident to the source region or the drain region via the buffer layer.

### BRIEF DESCRIPTION OF THE DRAWINGS

To describe the technical solutions in the embodiments of the present disclosure more clearly, the accompanying drawings of the embodiments are briefly described below. It should be understood that the drawings described below refer only to some embodiments of the present disclosure, and not to restrict the present disclosure, wherein:

FIG. 1 is a schematic structural view of a prior art thin film transistor;

FIG. 2 is a schematic structural view of a thin film transistor according to an embodiment of the present disclosure;

FIG. 3 is a schematic flow chart of a method for fabricating a thin film transistor according to an embodiment of the present disclosure;

FIG. 4 is a schematic flow chart of another method for fabricating a thin film transistor according to an embodiment of the present disclosure;

FIG. 5 is a block diagram showing an embodiment of an array substrate; and

FIG. 6 is a block diagram showing an embodiment of a display panel.

### DETAILED DESCRIPTION

In order to make the technical solutions and advantages of the embodiments of the present disclosure more comprehensible, the technical solutions of the embodiments of the present disclosure are clearly and completely described below with reference to the accompanying drawings. Obviously, the described embodiments are only a part but not all of the embodiments of the present disclosure. Based on the described embodiments of the present disclosure, all other embodiments obtained by those skilled in the art without creative efforts shall also fall within the protection scope of the present disclosure.

For the purposes of the surface description below, as used in the drawings, the terms “upper”, “lower”, “left”, “right”, “vertical”, “horizontal”, “top”, “bottom” and the derivative words should refer to the present disclosure. The terms “overlay”, “above”, “positioned on” or “positioned on top of” mean that a first element, such as a first structure, exists on a second element, such as a second structure, wherein an intermediate element such as an interface structure may exist between the first element and the second element. The term “contacting” means the first element of the first structure and the second element of the second structure are connected, and other elements may exist or not exist on the interfaces of the two elements.

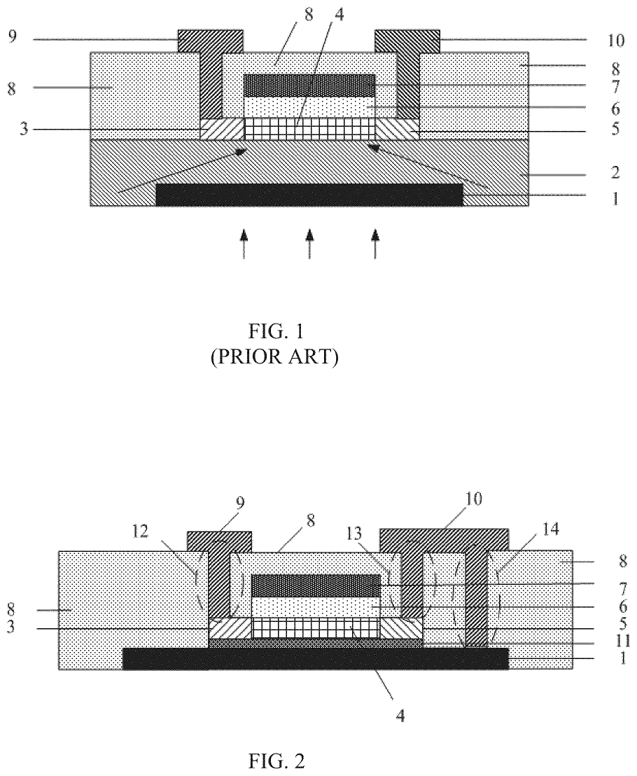

When an oxide TFT of a top gate structure is fabricated, a light shielding layer is usually formed on the panel to shield light. As shown in FIG. 1, an oxide TFT structure of a top gate structure includes a light shielding layer 1, a silicon oxide layer 2, a first conductive region 3, a channel region 4, a second conductive region 5, a gate insulating layer 6, a gate electrode 7, an interlayer insulating layer 8, a source electrode 9, and a drain electrode 10. Here, the arrow in the figure represents the direction of the optical path, and the silicon oxide layer serves as a buffer layer. Light can pass through the silicon oxide layer. In the solution of FIG. 1, the silicon oxide layer is disposed as a whole layer and has a thick thickness. The light shielding layer is disposed to block only light incident to the channel region perpendicular to the direction of the light shielding layer. Light that is not perpendicular to the direction of the light shielding layer can still be incident from the side surface of the silicon oxide layer to the channel region, affecting the electrical properties of the oxide in the channel region. Such a top gate structure oxide TFT has a poor light-shielding effect on the channel region, and the TFT has poor operational stability.

The embodiments of the present disclosure provide a thin film transistor, a method for fabricating the same, an array substrate, and a display panel. The embodiments of the present disclosure can enhance the light shielding effect on a channel region of a thin film transistor, thereby improving the light stability of the thin film transistor and improving the operation stability of the thin film transistor.

A thin film transistor provided by an embodiment of the present disclosure, as shown in FIG. 2, includes a light shielding layer 1, a buffer layer 11 on the light shielding layer 1, and an active layer (e.g., a semiconductor layer) on the buffer layer 11. The active layer includes a channel region 4 and a source region and a drain region on two sides of the channel region 4, wherein the thickness of the buffer layer 11 is set such that light cannot enter the channel region via the buffer layer 11.

In FIG. 2, one of the source region and the drain region may be set as the first conductive region 3 located on the left side of the channel region, and the other of the source region and the drain region may be set as the second conductive region 5 located on the right side of the channel region. For convenience of description, the following description will be made by taking the source region as the first conductive region 3 and the drain region as the second conductive region 5 and the active layer as a semiconductor layer as an example.

In an embodiment, the thickness of the buffer layer is also set such that light cannot be incident to the channel region via the source region and the drain region.

The thin film transistor further includes a gate insulating layer 6 on the channel region 4, a gate electrode 7 on the gate insulating layer 6, an insulating layer 8 on the first conductive region, the second conductive region, and the source electrode 9, and the drain electrode 10 on the insulating layer 8 (for example, an interlayer insulating layer). The insulating layer 8 is on the gate electrode 7, the first conductive region 3, the second conductive region 5, the buffer layer 11, and the light shielding layer 1. The insulating layer 8 includes a first via 12, a second via 13, and a third via 14. The source 9 is connected to the first conductive region 3 through the first via 12. The drain electrode 10 is connected to the second conductive region 5 through the second via 13. The drain electrode 10 is connected to the light shielding layer 1 through the third via 14. It can be understood that the transistor can also be disposed such that its source electrode is connected to the light shielding layer through the third via.

A thin film transistor according to an embodiment of the present disclosure is configured such that a thickness of a buffer layer of the thin film transistor is set such that light cannot enter the channel region via the buffer layer. In an embodiment, the thickness of the buffer layer of the thin film transistor is further set such that light cannot be incident to the source region or the drain region via the buffer layer. By setting the thickness of the buffer layer in such a manner that light originally incident on the active layer (for example, the semiconductor layer) is completely blocked, so that light cannot be incident on the channel region of the active layer through the buffer layer, thereby the light shielding effect on the channel region of the thin film transistor can be enhanced. Thus, the light stability of the thin film transistor can be improved and the working stability of the thin film transistor can be improved.

It should be noted that the first conductive region 3 and the second conductive region 5 are regions of the semiconductor layer subjected to the conductivization treatment, and the channel region 4 is a region of the semiconductor layer that has not been subjected to the conductivization treatment.

In an embodiment, the light shielding layer is a metal light shielding layer. The “metal” here includes metal simple substances and metal alloys. It should be noted that the light shielding layer is connected to the low potential end of the source electrode and the drain electrode of the thin film transistor, so that the induced charge of the metal light shielding layer can be prevented from affecting the characteristics of the thin film transistor. In the thin film transistor shown in FIG. 2 provided by the embodiment of the present disclosure, the drain electrode serves as a low potential end of the source electrode and the drain electrode, and the light shielding layer is connected to the drain electrode. Similarly, when the source electrode serves as the low potential end of the source electrode and the drain electrode, the source electrode is connected to the light shielding layer through the third via.

In an embodiment, the material of the light shielding layer includes a molybdenum-niobium alloy (MoNb), and the material of the buffer layer includes aluminum oxide (AlOx). Here, the “x” may include a non-stoichiometric ratio. Of course, the material of the light shielding layer may also be other metal materials that can achieve the light shielding function, and the buffer layer may also use other metal oxides.

In an embodiment, the aluminum oxide is formed by anodizing an aluminum-neodymium alloy.

It should be noted that AlOx as a buffer layer is formed from AlNd by anodization and has good compactness. Compared with the SiOx layer formed by thinning in the prior art, the problem of a large number of pores and poor compactness of the film resulted from depositing a thin layer of SiOx can be avoided. Under the same film thickness condition, the dielectric constant of AlOx is greater than the dielectric constant of silicon oxide. In the embodiment of the present disclosure, AlOx serves as the buffer layer, and the performance of the thin film transistor can be improved while thinning the buffer layer.

In an embodiment, the buffer layer has a thickness in the range of about 100 nm to about 200 nm.

In an embodiment, the size of the buffer layer is smaller than the size of the light shielding layer in a direction parallel to the buffer layer. In other words, the projection of the buffer layer on the light shielding layer falls within the light shielding layer. Therefore, in an embodiment, in the thin film transistor shown in FIG. 2, the first via 12, the second via 13, and the third via 14 may be formed in the same etching process.

In thin film transistor of the prior art, the silicon oxide buffer layer is thick and disposed as a whole layer. Using one etching process does not guarantee the third via hole. Thus, the etching of the third via, the first via, and the second via is divided into two steps. The thin film transistor provided by the embodiments of the present disclosure has a thinner thickness of the buffer layer and the projection of the buffer layer falls within the light shielding layer, and the thicknesses of insulating layer in the semiconductor layer and the light shielding layer are substantially uniform. Therefore, the vias can be simultaneously etched in the conductive region and the light shielding layer region. That is, the first via, the second via, and the third via can be formed by the same etching process. While ensuring the accuracy of via etching, the thin film transistor preparation process is simplified, and the process difficulty of thin film transistor fabrication is reduced.

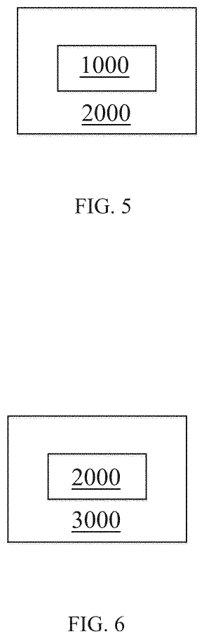

An array substrate according to the embodiments of the present disclosure includes the thin film transistor according to the embodiments of the present disclosure. FIG. 5 is a block diagram showing an embodiment of an array substrate. As shown in FIG. 5, an array substrate 2000 includes a thin film transistor 1000. In this example embodiment, the thin film transistor 1000 is a thin film transistor as shown in FIGS. 1 and 2.

A display panel according to the embodiment of the present disclosure includes the array substrate according to the embodiment of the present disclosure. FIG. 6 is a block diagram showing an embodiment of a display panel. As shown in FIG. 6, a display panel 3000 includes an array substrate 2000. In this example embodiment, the array substrate 2000 is an array substrate as shown in FIG. 5.

For example, the display panel provided by the embodiment of the present disclosure may be an organic light emitting diode (OLED) display panel, a liquid crystal display panel, or the like.

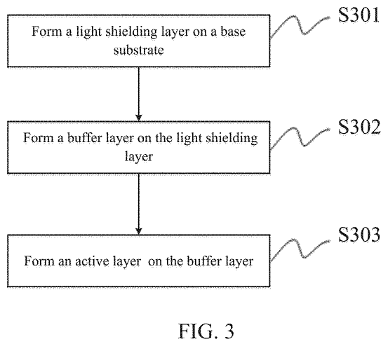

A method for fabricating a thin film transistor according to an embodiment of the present disclosure, as shown in FIG. 3, the method includes:

S301: forming a light shielding layer on the base substrate;

S302: forming a buffer layer on the light shielding layer; and

S303: forming an active layer (e.g., a semiconductor layer) on the buffer layer. The active layer includes a channel region, a source region, and a drain region on two sides of the channel region. The thickness of the buffer layer is set such that light cannot be incident to the channel region via the buffer layer. In an embodiment, the thickness of the buffer layer is also set such that light cannot enter the source region or the drain region via the buffer layer.

In an embodiment, the light shielding layer includes a metal and the buffer layer may include a metal oxide.

In an embodiment, forming the light shielding layer and forming the buffer layer includes depositing a first metal layer (e.g., a molybdenum-niobium alloy) as a light shielding layer on the base substrate (e.g., a glass substrate), forming a second metal layer (e.g., an aluminum-neodymium alloy) (e.g., deposited) on the first metal layer (e.g., a molybdenum-niobium alloy), and oxidizing the second metal layer to form the buffer layer.

In an embodiment, the aluminum-neodymium alloy may be oxidized using an anodizing process to obtain aluminum oxide served as a buffer layer.

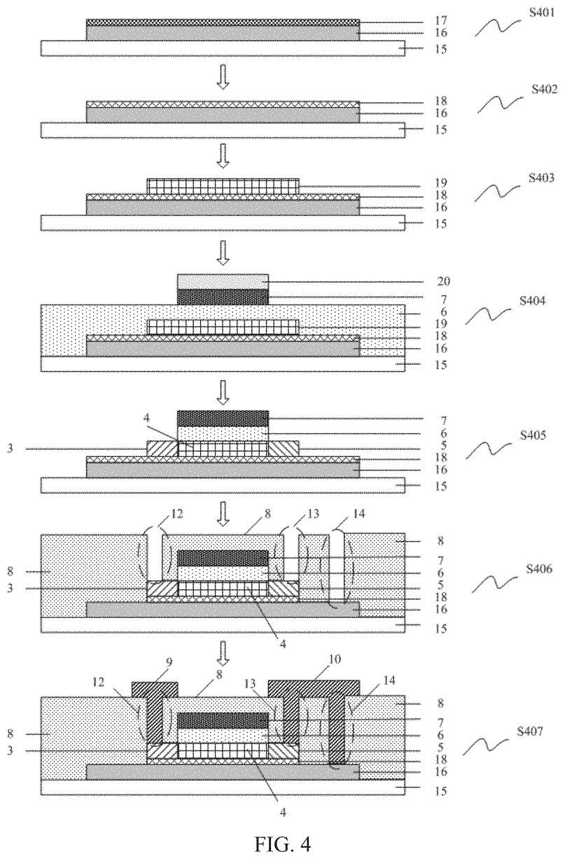

Taking the light shielding layer material includes MoNb, the buffer layer material includes AlOx and the active layer includes a semiconductor layer as an example, the method for preparing a thin film transistor as shown in FIG. 2 according to embodiments of the present disclosure is exemplified. The method is shown in FIG. 4 with details as follows:

S401: depositing MoNb 16 on a glass substrate 15, depositing a thin layer of AlNd 17 on the MoNb 16, coating a photoresist, and forming a light shielding layer by photolithography. In addition to the light-shielding effect, MoNb can also have good adhesion to the glass substrate during the preparation of the thin film transistor. The thickness of the thin layer of AlNd may be, for example, 100 nm to 200 nm.

S402: Applying a voltage to the light shielding layer, and anodizing AlNd 17 such that all AlNd 17 is oxidized to AlOx 18 serving as a buffer layer.

S403: Depositing a semiconductor material, and etching to form a semiconductor layer 19.

S404: Depositing a gate insulating layer 6 material, depositing a gate electrode 7 material, coating a photoresist 20 on the top metal layer, and etching the gate pattern.

S405: Forming a gate insulating layer 6 by self-aligned downward etching with using the gate pattern as a mask. After the etching reaches the semiconductor layer, the semiconductor layer is conductivized to obtain a first conductive region 3 and a second conductive region 5. The buffer layer exceeding the first conductive region and the second conductive region is etched, thereby the light shielding layer in regions other than the first conductive region and the second conductive region is exposed.

S406: Depositing an interlayer insulating layer and forming a first via 12, a second via 13, and a third via 14 by using a dry etching process.

S407: Depositing a source/drain metal layer, performing an etching to form a source electrode 9 and a drain electrode 10 (wherein the positions of the source electrode and the drain electrode are interchangeable, the electrode 9 may be used as a drain electrode and the electrode 10 may be used as a drain electrode).

The source 9 is connected to the first conductive region 3 through the first via 12. The drain 10 is connected to the second conductive region 5 through the second via 13. The drain 10 is connected to the MoNb 16 layer through the third via 14.

It should be noted that, in step S402, AlNd is completely oxidized to AlOx. In the process of preparing the thin film transistor, the voltage applied to the light shielding layer may be controlled, so that AlNd is not completely oxidized, and a certain thickness of the AlNd layer is retained.

In the method for fabricating a thin film transistor provided by the embodiment of the present disclosure, an anodizing process is used to oxidize the aluminum-neodymium alloy to obtain an aluminum oxide as a buffer layer. The process is simple and easy to implement.

In summary, the embodiments of the present disclosure provide the thin film transistor, the array substrate, the display panel, and the method for fabricating the thin film transistor. The buffer layer is a thin buffer layer and the thickness of the buffer layer is set such that the light cannot be incident to the channel region via the buffer layer. That is, the thickness of the buffer layer is set such that light originally incident on the active layer (for example, the semiconductor layer) is completely blocked, so that light cannot be incident on the active layer through the buffer layer. The light shielding effect of the channel region of the thin film transistor can be enhanced and the light stability of the thin film transistor can be improved, thereby the working stability of the thin film transistor is improved. In addition, in the thin film transistor provided by the embodiments of the present disclosure, the projection of the buffer layer with a thin thickness on the light shielding layer falls within the light shielding layer, and the thickness of the insulating layer corresponding to the active layer and the thickness of the insulating layer corresponding to the light shielding layer are substantially the same. Therefore, vias can be simultaneously etched in the conductive region and the light shielding layer region. That is, the first via, the second via, and the third via can be formed by one etching process. Thus, the thin film transistor fabrication process is simplified and the process difficulty of thin film transistor fabrication is reduced while ensuring the etching precision of the vias.

It will be apparent to those skilled in the art that various modifications and variations can be made in the present disclosure without departing from the spirit and scope of the disclosure. Thus, it is intended that the present disclosure cover the modifications and variations of the present disclosure.

1. A thin film transistor comprising:
a light shielding layer;
a buffer layer on the light shielding layer; and
an active layer on the buffer layer, the active layer comprising a channel region and a source and a drain region respectively on two sides of the channel region, wherein a thickness of the buffer layer is set such that light cannot be incident on the channel region via the buffer layer.

2. The thin film transistor according to claim 1, wherein the light shielding layer comprises a metal and the buffer layer comprises a metal oxide.

3. The thin film transistor according to claim 2, wherein the material of the light shielding layer comprises a molybdenum-niobium alloy, and wherein the material of the buffer layer comprises aluminum oxide.

4. The thin film transistor according to claim 3, wherein the aluminum oxide is formed by anodizing an aluminum-neodymium alloy.

5. The thin film transistor according to claim 1, wherein the buffer layer has a thickness ranging from about 100 nm to about 200 nm.

6. The thin film transistor according to claim 1, wherein a projection of the buffer layer on the light shielding layer falls within the light shielding layer.

7. The thin film transistor according to claim 5, wherein the thin film transistor further comprises:
a gate insulating layer on the channel region;
a gate electrode on the gate insulating layer;
an insulating layer on the gate electrode, the source region, the drain region, the buffer layer, and the light shielding layer; and
a source electrode and a drain electrode on the insulating layer, wherein the insulating layer comprises a first via, a second via, and a third via, wherein the source electrode and the drain electrode are connected to the source region and the drain region through the first via and the second via, respectively, and wherein one of the drain electrode and the drain is connected to the light shielding layer through the third via.

8. The thin film transistor according to claim 1, wherein a thickness of the buffer layer is further set such that light cannot be incident on the source region or the drain region via the buffer layer.

9. An array substrate comprising the thin film transistor according to claim 1.

10. A display panel comprising the array substrate according to claim 9.

11. A method of fabricating a thin film transistor, wherein the method comprises:
forming a light shielding layer on a base substrate;
forming a buffer layer on the light shielding layer; and
forming an active layer on the buffer layer, wherein the active layer comprises a channel region and source and drain regions respectively on two sides of the channel region, wherein the thickness of the buffer layer is set such that light cannot be incident on the channel region via the buffer layer.

12. The method according to claim 11, wherein the light shielding layer comprises a metal and the buffer layer comprises a metal oxide.

13. The method according to claim 12, wherein forming the light shielding layer and forming the buffer layer comprises:
forming a first metal layer as the light shielding layer on the substrate;
forming a second metal layer on the first metal layer; and
performing an oxidation treatment on the second metal layer to form the buffer layer.

14. The method according to claim 13, wherein the first metal comprises a molybdenum-niobium alloy and the second metal layer comprises an aluminum-neodymium alloy; and
wherein the oxidation treatment comprises anodizing the aluminum-neodymium alloy to obtain aluminum oxide.

15. The method according to claim 11, the method further comprising:
forming a gate insulating layer on the channel region;
forming a gate electrode on the gate insulating layer;
forming an insulating layer on the gate electrode, the source region, the drain region, the buffer layer, and the light shielding layer;
forming a first via, a second via, and a third via on the insulating layer, wherein the first via reaches an upper surface of the source region, the second via reaches an upper surface of the drain region, and the third via reaches an upper surface of the light shielding layer not covered by the buffer layer; and
forming a source electrode and a drain electrode on the insulating layer, wherein the source electrode and the drain electrode are connected to the source region and the drain region through the first via and the second via respectively, and wherein one of the source electrode and the drain electrode is connected to the light shielding layer through the third via.

16. The method according to claim 15, wherein the first via, the second via, and the third via are formed in the same etching process.

17. The method according to claim 11, wherein a thickness of the buffer layer is further set such that light cannot be incident on the source region or the drain region via the buffer layer.

18. The thin film transistor according to claim 2, wherein a thickness of the buffer layer is further set such that light cannot be incident on the source region or the drain region via the buffer layer.

19. The thin film transistor according to claim 3, wherein a thickness of the buffer layer is further set such that light cannot be incident on the source region or the drain region via the buffer layer.

20. The thin film transistor according to claim 4, wherein a thickness of the buffer layer is further set such that light cannot be incident on the source region or the drain region via the buffer layer.
